(19) United States
(12) Patent Application Publication
(10) Pub. No.: US 2014/0281187 A1
(43) Pub. Date: Sep. 18, 2014

(54) ELECTRONIC APPARATUS, METHOD OF CREATING SNAPSHOT IMAGE, AND PROGRAM

(71) Applicant: SONY CORPORATION, Tokyo (JP)

(72) Inventors: Masahiro TAMORI, Kanagawa (JP); Kan IIBUCHI, Kanagawa (JP); Satoru IWASAKI, Tokyo (JP); Kazumi SATO, Kanagawa (JP)

(73) Assignee: SONY CORPORATION, Tokyo (JP)

(21) Appl. No.: 14/157,586

(22) Filed: Jan. 17, 2014

(30) Foreign Application Priority Data
Mar. 15, 2013 (JP) 2013-052691

(51) Int. Cl. G06F 11/14; G11C 7/10

(52) U.S. Cl. CPC G06F 11/1446; G11C 7/1072
USPC 711/104

(57) ABSTRACT

An electronic apparatus includes a volatile memory, a swap device, and a control unit. The control unit is configured to divide data loaded in the volatile memory between an activation start and a specific time point after the activation start into data used to create a snapshot image and data stored in the swap device.

### CROSS REFERENCE TO RELATED APPLICATIONS

This application claims the benefit of Japanese Priority Patent Application JP 2013-052691 filed Mar. 15, 2013, the entire contents of which are incorporated herein by reference.

### BACKGROUND

The present technology relates to an electronic apparatus that is activated by using a snapshot image, a method of creating a snapshot image, and a program.

In related art, as a technology for performing high-speed activation of various electronic apparatuses such as a digital camera, a television receiver, and a PC (personal computer), hibernation, snapshot boot, and the like are known.

For example, Japanese Patent Application Laid-open No. 2007-334383 discloses a technology relating to hibernation. The hibernation is such a technology that a memory image in a volatile memory is stored in a nonvolatile memory before shutdown, and the memory image is read therefrom on activation, thereby reproducing a state before the shutdown.

Further, for example, Japanese Patent Application Laid-open No. 2011-116242 discloses a technology relating to snapshot boot. The snapshot boot is such a technology that a memory image for high-speed activation called snapshot image is prepared in advance, and the snapshot image is used on activation, thereby activating an electronic apparatus.

There is a difference between the hibernation and the snapshot boot. In the hibernation, the activation is performed on the basis of different memory images each time. In contrast, in the snapshot boot, as a general rule, the activation is performed on the basis of the same memory image each time

### SUMMARY

In an electronic apparatus, a short activation time is desirable, and therefore a technology capable of further reducing the activation time is expected.

In view of the above-mentioned circumstances, it is desirable to provide a technology such as an electronic apparatus capable of shortening an activation time.

According to an embodiment of the present disclosure, there is provided an electronic apparatus including a volatile memory, a swap device, and a control unit.

The control unit is configured to divide data loaded in the volatile memory between an activation start and a specific time point after the activation start into data used to create a snapshot image and data stored in the swap device.

In the electronic apparatus according to the embodiment of the present technology, a part of the data loaded into the volatile memory between the activation start and the specific time point after the activation start is used to create the snapshot image. As a result, the size of the snapshot image is reduced, and a system activation time can be shortened.

In the electronic apparatus, the control unit may perform a profiling mode in which, from data loaded in the volatile memory between the activation start and the specific time point after the activation start, data to be used to create the snapshot image is determined by profiling.

As a result, the control unit can appropriately determine the data to be used to create the snapshot image.

In the electronic apparatus, the control unit may determine data to be used to create the snapshot image by profiling relating to reading data to the volatile memory in the profiling mode.

As a result, the control unit can appropriately determine the data to be used to create the snapshot image.

In the electronic apparatus, the control unit may stop a read-ahead function of an OS (operating system) in the profiling mode.

As a result, it is possible to prevent the data originally unnecessary for the activation from being included in the snapshot image by the read-ahead function of the OS.

In the electronic apparatus, the control unit may create a list relating to which data is used to create the snapshot image by the profiling.

In the electronic apparatus, after the profiling mode is performed, the control unit may read the data determined to be used to create the snapshot image by the profiling to the volatile memory and perform a snapshot image creation mode in which the snapshot image is created based on the data read to the volatile memory.

As a result, it is possible to appropriately create the snapshot image.

In the electronic apparatus, the control unit may stop a read-ahead function of an OS (operating system) in the snapshot image creation mode.

As a result, it is possible to prevent the data originally unnecessary for the activation from being included in the snapshot image by the read-ahead function of the OS.

In the electronic apparatus, the control unit may perform, prior to the profiling mode, a preparation mode in which the data is loaded into the volatile memory by normal activation from the activation start until the specific time point after the activation start.

In the electronic apparatus, the control unit may perform swap-out of data used in an application program, of the data loaded into the volatile memory between the activation start and the specific time point after the activation start, to the swap device in the preparation mode.

In the electronic apparatus, after the swap-out of the data is performed, the swap device may be brought into a read-only state.

In the electronic apparatus, the control unit may delete the application program and a page cache, from the data loaded into the volatile memory between the activation start and the specific time point after the activation start, in the preparation mode.

In the electronic apparatus, the control unit may create, in the preparation mode, a snapshot image at a stage prior to creation of a last snapshot image based on data in the volatile memory, which is obtained after the swap-out of the data used in the application program and the deletion of the application program and the page cache.

In the electronic apparatus, the control unit may determine the number of pieces of data to be used to create the snapshot image for the data determined to be used to create the snapshot image by the profiling.

As a result, it is possible to further shorten the activation time.

In the electronic apparatus, the control unit may determine the number of pieces of data to be used to create the snapshot image based on a speed at a time when the data is read to the volatile memory and a process time spent on reading the data when a page fault occurs.

As a result, it is possible to further shorten the activation time.

In the electronic apparatus, the control unit may further determine data to be used to create the snapshot image, from the data determined to be used to create the snapshot image by the profiling.

As a result, it is possible to further shorten the activation time.

In the electronic apparatus, the control unit may associate the data with time information that indicates time when the data is read to the volatile memory in the profiling mode, determines a time zone in which the data is highly frequently read based on the time information, and creates the snapshot image by using the data read to the volatile memory in the time zone in which the data is highly frequently read.

As a result, it is possible to further shorten the activation time.

According to another embodiment of the present technology, there is provided a method of creating a snapshot image including dividing data loaded in a volatile memory between an activation start and a specific time point after the activation start into data used to create a snapshot image and data stored in a swap device.

The snapshot image is created based on the data used to create the snapshot image.

According to another embodiment of the present technology, there is provided a program causing an electronic apparatus to execute dividing data loaded in a volatile memory between an activation start and a specific time point after the activation start into data used to create a snapshot image and data stored in a swap device, and creating the snapshot image based on the data used to create the snapshot image.

As described above, according to the present disclosure, it is possible to provide a technology such as the electronic apparatus capable of shortening the activation time.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a block diagram showing the internal structure of an electronic apparatus according to an embodiment of the present technology;

FIG. 2 is a flowchart showing a process of creating a snapshot image;

FIG. 3 is a flowchart showing a process in a preparation mode;

FIG. 4 is a schematic diagram for explaining the process in the preparation mode;

FIG. 5 is a flowchart showing a process in a profiling mode;

FIG. 6 is a schematic diagram for explaining the process in the profiling mode;

FIG. 7 is a diagram showing an example of an image list generated by obtaining a history of a page fault;

FIG. 8 is a diagram showing an example of the image list generated by obtaining the history of the page fault;

FIG. 9 is a flowchart showing a process in a snapshot image creation mode;

FIG. 10 is a schematic diagram for explaining the process in the snapshot image creation mode;

FIG. 11 is a diagram showing the state where a snapshot image according to a comparative example is used to perform activation;

FIG. 12 is a diagram showing the state where a snapshot image according to the present technology is used to perform activation;

FIG. 13 is a diagram for explaining meanings of a left-hand side and a right-hand side of an expression; and

FIG. 14 is a diagram for explaining a process of an electronic apparatus according to another embodiment of the present technology.

### DETAILED DESCRIPTION OF EMBODIMENTS

Hereinafter, embodiments of the present disclosure will be described with reference to the drawings.

### First Embodiment

### Entire Structure of Electronic Apparatus and Structures of Units

FIG. 1 is a block diagram showing the internal structure of an electronic apparatus 10 according to a first embodiment of the present technology. The electronic apparatus 10 according to the present technology is, for example, a digital camera, a television receiver, a PC (personal computer), or the like.

As shown in FIG. 1, the electronic apparatus 10 is provided with a control unit 1, a main memory 2, a DMAC (direct memory access controller) 3, a storage device 4, and a swap device 5. Those units are connected to each other via a bus 6.

The control unit 1 is formed of a CPU (central processing unit), for example. The control unit 1 performs overall control for the entire electronic apparatus 10 on the basis of various programs stored in the storage device 4.

The main memory (volatile memory) 2 is formed of a RAM (random access memory), for example. The main memory 2 is a volatile memory used as a work area for the control unit 1.

The storage device 4 is formed of an HDD (hard disc drive), an SDD (solid state drive), a semiconductor memory such as a NAND flash memory, or a combination of those. In the storage device 4, an OS (operating system), an application program, or the like is fixedly stored. Further, in the storage device 4, a snapshot image and the like created through a process to be described below is also stored (after the snapshot image is created).

The snapshot image according to the present technology is a memory image obtained by excluding memory data which is originally unnecessary for the activation. The snapshot image is managed for each page. The page is a minimum unit for managing the main memory 2, and the size of the page is 4 KB, for example.

The swap device 5 is formed of an HDD (hard disc drive), an SDD (solid state drive), a semiconductor memory such as a NAND flash memory, or a combination of those. The swap device 5 can have any form as long as the swap device can fixedly store data. In the swap device 5, data unnecessary for activation completion of the electronic apparatus 10 is stored for each page.

In the figure, an example in the case where the storage device 4 and the swap device 5 are separately provided is shown. However, the swap device 5 may be integrally formed with the storage device 4. In other words, the storage device 4 may double as the swap device 5.

The DMAC 3 controls transmission and reception of data by DMA between the main memory 2 and the storage device 4 and between the main memory 2 and the swap device 5. The DMAC 3 reduces a load on the control, unit 1.

(Explanation of Operation)

Next, a process of the electronic apparatus 10 (control unit 1) according to the present technology will be described. The electronic apparatus 10 according to the present technology performs a process of creating a snapshot image to be used to perform high-speed activation of the electronic apparatus 10.

Typically, the control unit 1 divides data loaded into the main memory 2 between an activation start and a time point when the snapshot image is created (specific time point after the activation start) into data used to create the snapshot image and data stored in the swap device 5. Then, the electronic apparatus 10 creates the snapshot image on the basis of the data used to create the snapshot image.

The process by the control unit 1 is roughly classified into a preparation mode, a profiling mode, and a snapshot image creation mode. In the following, those three modes will be described in detail.

FIG. 2 is a flowchart showing the process of creating the snapshot image.

As shown in FIG. 2, first, when the activation is started, the control unit 1 determines whether a current mode is the preparation mode or not (Step 101). When it is determined that the current mode is the preparation mode (Yes in Step 101), the control unit 1 performs the preparation mode (Step 102). After the control unit performs the preparation mode, the control unit 1 performs reactivation (Step 103) and returns to Step 101.

The preparation mode is a mode as a preparation stage of the profiling mode in which data originally necessary for the activation is determined by profiling.

At a time of the activation start, when it is determined that the current mode is not the preparation mode (No in Step 101), the control unit 1 determines whether the current mode is the profiling mode or not (Step 104). When it is determined that the current mode is the profiling mode (Yes in Step 104), the control unit 1 performs the profiling mode (Step 105). After the control unit 1 performs the profiling mode, the control unit 1 performs reactivation (Step 106) and returns to Step S101.

The profiling mode is a mode in which, from data loaded into the main memory 2 between the activation start and the time point when the snapshot image is created, data originally necessary for the activation is determined by the profiling.

At a time of the activation start, when it is determined that the current mode is neither the preparation mode nor the profiling mode (No in Step 104), the control unit 1 determines whether the current mode is the snapshot image creation mode or not (Step 107). When it is determined that the current mode is the snapshot image creation mode (Yes in Step 107), the control unit 1 performs the snapshot image creation mode (Step 108). After the control unit 1 performs the snapshot image creation mode, the control unit 1 performs the reactivation (Step 109) and returns to Step S101.

In the snapshot image creation mode, the data determined to be used to create the snapshot image by the profiling is read to the main memory 2, and the snapshot image is created on the basis of the data in the main memory 2.

<<Preparation Mode>>

Subsequently, the preparation mode will be described in detail. FIG. 3 is a flowchart showing a process in the preparation mode. FIG. 4 is a schematic diagram for explaining the process in the preparation mode.

With reference to FIGS. 3 and 4, in the preparation mode, first, the control unit 1 starts the activation of the electronic apparatus 10 in the same way as normal activation (Step 201). In this case, first, the control unit 1 executes a boot loader and reads an OS (kernel) into the main memory 2 on a page basis from the storage device 4. After that, the control unit 1 starts up (initializes) the OS.

Then, the control unit 1 reads an application program on the page basis from the storage device 4 into the main memory 2 to starts up (initialize) the application. After that, the control unit 1 executes the application program (Step 202). Along with the execution of the application program, the control unit 1 reads data (file) on the page basis from the storage device 4 to the main memory 2 as necessary. Further, along with the execution of the application program, the control unit 1 performs various calculations and stores calculation results in the main memory 2 on the page basis.

Then, until the snapshot image creation time point (until the specific time point after the activation start), the control unit 1 continues the execution of the application program. The snapshot image creation time point can be arbitrarily set from a viewpoint of achievement of the activation at higher speed. For example, the snapshot image creation time point may be a time point when the execution of a first application after the startup of the OS is completed or may be a time point when the execution of a second application is completed.

FIG. 4 shows the data loaded into the main memory 2 between the activation start and the snapshot image creation time point. As shown in FIG. 4, at the snapshot image creation time point, in the main memory 2, the data such as the OS (kernel) and the application program read from the storage device 4 is loaded. Further, in the main memory 2, data used in the application program and data such as a page cache are loaded.

The data used in the application program includes data calculated by using the application program. The page cache (buffer) is data which may be used later and thus remains in the main memory 2.

Upon reaching the snapshot image creation time point, the control unit 1 enables the swap device 5 to perform swap-out of data (anonymous page) used in the application program to the swap device 5 (Step 203). After that, the swap device 5 is adjusted to a read-only state. The data that is subjected to swap-out can be compressed. The compression may be performed by hardware or software.

In addition, upon reaching the snapshot image creation time point, the control unit 1 deletes, from the main memory 2, the page of the application program, the page cache, and the like loaded into the main memory 2 (Step 204).

The data used in the application program is subjected to the swap-out, and the application program and the page cache are deleted, with the result that the OS (kernel) remains in the main memory 2. In the main memory 2, data or the like that is used in firmware may remain. On the basis of the data that remains in the main memory 2, the control unit 1 creates the memory image on the page basis (Step 205). That is, the control unit 1 creates the memory image including the OS (and the data used in the firmware).

Hereinafter, the memory image is referred to as a minimization image. The minimization image is a snapshot image at a stage prior to creation of a final snapshot image and a minimized image including the data (OS (kernel)) as a minimum requirement for creating the snapshot image.

When the minimization image is created, the control unit 1 stores the minimization image in the storage device 4 (Step 206).

Here, a comparative example will be described. Generally, the snapshot image is created on the basis of the memory image of the main memory 2 as shown in FIG. 4. That is, the data loaded into the main memory 2 is entirely used at the snapshot image creation time point, to create the snapshot image. However, in the case where the snapshot image is created by the method, data originally unnecessary for the activation may be included in the snapshot image.

In recent years, the size of an application program tends to be increased. Along with the increase, the snapshot image also tends to be increased in size. However, a read speed from the storage device 4 to the main memory 2 is not increased, so it takes a longer time to read the snapshot image to the main memory 2. As a result, it takes time to complete the activation.

In view of this, in the present technology, the process of dividing the data loaded into the main memory 2 between the activation start and the specific time point after the activation start into the data used to create the snapshot image and the data stored in the swap device 5 is performed.

That is, in the present technology, from the data included in the memory image as shown in FIG. 4, data originally necessary for the activation is determined, and the data determined is used to create the snapshot image. On the other hand, data originally unnecessary for the activation is stored in the swap device 5.

Here, as described above, in the preparation mode, the data used in the application program is subjected to swap-out to the swap device 5, and the data is stored in the swap device 5.

However, this does not mean that the entire data used in the application program is originally unnecessary for the activation. That is, this means that, at a stage prior to the determination of the data originally necessary for the activation, the data is stored in the swap device 5, with the data originally necessary for the activation and the data originally unnecessary for the activation included therein.

<<Profiling Mode>>

Subsequently, the profiling mode will be described. FIG. 5 is a flowchart showing a process in the profiling mode. FIG. 6 is a schematic diagram for explaining the process in the profiling mode.

In the profiling mode, from data loaded into the main memory 2 between the activation start and the snapshot image creation time point, data to be used to create the snapshot image is determined.

The profiling mode is performed after reactivation after the preparation mode is completed (see, FIG. 2). With reference to FIGS. 5 and 6, in the profiling mode, the control unit 1 first uses a minimization image created in the preparation mode to start the activation (Step 301). In this case, first, the control unit 1 executes the boot loader and reads data included in the minimization image on the page basis from the storage device 4 to the main memory 2.

Then, the control unit 1 stops a read-ahead function by the OS (Step 302). Here, in the case where the read-ahead function of the OS is executed, data originally unnecessary for the activation is read to the main memory 2 by the read-ahead function, and the data may be reflected on the profiling. In this case, the data originally unnecessary for the activation may be included in the snapshot image. In view of this, in the present technology, the read-ahead function by the OS is stopped. As a result, it is possible to prevent the data originally unnecessary for the activation from being included in the snapshot image due to the read-ahead function of the OS.

Then, the control unit 1 starts profiling relating to which data is to be used to create the snapshot image (Step 303). The profiling is performed by obtaining a history of a page fault that occurs when the data is read from the storage device 4 or the swap device 5 to the main memory 2.

Then, the control unit 1 reads the application program from the storage device 4 on the page basis and starts up (initializes) the application. After that, the control unit 1 executes the application program (Step 304). Along with the execution of the application program, the control unit 1 reads data (file) from the storage device 4 to the main memory 2 on the page basis when necessary. In addition, the control unit 1 reads the data (anonymous page) used in the application program to the main memory 2 from the swap device 5 when necessary.

When the application program or the file is read from the storage device 4, the page fault occurs. Further, when the data (anonymous page) used in the application program is read from the swap device 5, the page fault occurs. The control unit 1 creates an image list relating to the history of the page fault.

Subsequently, the control unit 1 continues the execution of the application program until an activation completion time point. Upon reaching the activation completion time point, the control unit 1 stops the profiling (Step 305). That is, the control unit 1 stops recording of the history of the page fault.

After that, the control unit 1 stores the history of the page fault in the storage device 4 as an image list (Step 306).

In this way, the control unit 1 automatically determines the data to be used to create the snapshot image. In other words, the control unit 1 automatically determines that the data read from the storage device 4 or the swap device 5 until the activation completion time point is data originally necessary for the activation.

FIGS. 7 and 8 are diagrams each showing an example of the image list generated by obtaining the history of the page fault. FIG. 7 shows an image list generated by obtaining the history of the page fault that occurs when the application program or the file is read from the storage device 4. FIG. 8 shows an image list generated by obtaining the history of the page fault that occurs when the data used in the application program is read from the swap device 5. Hereinafter, the image list shown in FIG. 7 is referred to as a program image list, and the image list shown in FIG. 8 is referred to as a data image list.

As shown in FIG. 7, in the program image list, file names and offsets (unit: byte, for example) are associated with each other. The offset indicates an offset degree of the file from a head of a file. Further, in the program image list, time information (unit: nsec, for example) when the application program is read to the main memory 2 is associated therewith.

It should be noted that the time information is not always necessary information and is used when a third embodiment to be described later is implemented. Typically, the program image list only has to include information by which the control unit 1 can determine where the file is stored in the storage device 4.

As shown in FIG. 8, in the data image list, virtual addresses of process information and virtual addresses of data used in corresponding processes are associated with each other. In addition, in the image list, time information (unit: nsec, for example) when the data used in the application program is read to the main memory 2 is associated therewith.

The time information is not always necessary information and is used when the third embodiment to be described later is implemented. Typically, the data image list only has to include information by which the control unit 1 can determine where the data is stored in the swap device 5.

<<Snapshot Image Creation Mode>>

Subsequently, the snapshot image creation mode will be described. FIG. 9 is a flowchart showing a process in the snapshot image creation mode. FIG. 10 is a schematic diagram for explaining the process in the snapshot image creation mode.

The snapshot image creation mode is performed after the completion of the profiling mode and the reactivation thereafter (see, FIG. 2). With reference to FIGS. 9 and 10, in the snapshot image creation mode, the control unit 1 first uses the minimization image to start activation (Step 401). In this case, first, the control unit 1 executes the boot loader to read the data included in the minimization image on the page basis from the storage device 4 to the main memory 2.

Then, the control unit 1 stops a read-ahead function by the OS (Step 402). As a result, it is possible to prevent the data originally unnecessary for the activation from being included in the snapshot image due to the read-ahead function of the OS.

Then, on the basis of the image list, the control unit 1 reads the data included in the image list to the main memory 2 (Step 403). In this case, on the basis of the image list (see, FIG. 7), the control unit 1 reads the application program and the file from the storage device 4 to the main memory 2 on the page basis. Further, on the basis of the image list (see, FIG. 8), the control unit 1 reads the data (anonymous page) used in the application program on the page basis (swap-in).

When the entire data included in the image list is read to the main memory 2, on the basis of the data read to the main memory 2, the control unit 1 creates the snapshot image (Step 404). After that, the control unit 1 performs the reactivation.

The snapshot created includes data originally necessary for the activation. On the other hand, data originally unnecessary for the activation is stored in the swap device 5.

(Operation and the Like)

In the following, the operation of the present technology will be described while referring to a comparative example.

FIG. 11 is a diagram showing the state where a snapshot image according to the comparative example is used to perform activation. FIG. 12 is a diagram showing the state where the snapshot image according to the present technology is used to perform the activation.

The snapshot image according to the comparative example is an image created by using entire data loaded into the main memory 2 at the time of the creation of the snapshot image, as shown in FIG. 4.

In the comparative example, first, a hoot loader is executed at a time when activation is started, and data (OS (kernel), application program, file, and anonymous page) included in the snapshot image is read from the storage device 4 to the main memory 2 on the page basis. After that, the system is restarted, and the activation is completed. The snapshot image according to the comparative example includes the data originally unnecessary for the activation, so it takes time to perform the activation.

Subsequently, a process when the activation is performed by using the snapshot image according to the present technology will be described with reference to FIG. 12. First, the control unit 1 executes the boot loader at a time when the activation is started, and the data (OS (kernel), application program, file, and anonymous page) included in the snapshot image is read from the storage device 4 to the main memory 2 on the page basis. After that, the system is restarted, and the activation is completed. The snapshot image according to the present technology does not include the data originally unnecessary for the activation, so it is possible to shorten time spent on the activation. Further, the data originally unnecessary for the activation is stored in the swap device 5.

The data stored in the swap device 5 as the data originally unnecessary for the activation is read from the swap device 5 to the main memory 2 when the data becomes necessary. In other words, even during the execution of the application program, the data stored in the swap device 5 as the data originally unnecessary for the activation is not read to the main memory 2, until the data becomes necessary. This means that the amount of use of the main memory 2 during the execution of the application program can be reduced, and a space of the main memory 2 can be increased.

Here, with reference to FIG. 4, the data loaded into the main memory 2 between the activation start and the snapshot image creation time point includes the OS (kernel), the application program, the data used in the application program, and the page cache. Further, the data used in the application program as described above includes data calculated by the application program.

For example, in some cases, up to the snapshot image creation time point, large-size data such as a lookup table may be calculated by the application program. For example, in the case where similar calculations are repeated a great number of times, an obvious calculation may be generated as a lookup table in order to increase a process speed. The lookup table is stored in the main memory 2 as the data used in the application program.

If the large-size data such as the lookup table is included in the snapshot image, the speed of the activation is reduced. In the comparative example, the entire data loaded into the memory at a time of the creation of the snapshot image is included in the snapshot image. Therefore, in the comparative example, in order to avoid inclusion of the large-size data such as the lookup table in the snapshot image, it is necessary to set a time point before the lookup table is calculated as the snapshot image creation time point.

In contrast, in the present technology, even if the time point after the large-size data such as the lookup table is calculated is set as the snapshot image creation time point, the data may be determined to be originally unnecessary for the activation as a result of the profiling. In this case, the large-size data such as the lookup table is not included in the snapshot image. Further, in the present technology, the large-size data such as the lookup table is stored in the swap device 5 and is read from the swap device 5 to the main memory 2 at the time point when the data becomes necessary.

That is, according to the present technology, it is possible to make the snapshot image more compact while delaying the snapshot image creation time point as compared to the comparative example. Therefore, the present technology is advantageous in terms of the time reduction for the activation.

### Second Embodiment

Next, a second embodiment according to the present technology will be described. In the second embodiment and embodiments subsequent thereto, points different from the first embodiment will be mainly described.

In the second embodiment, for the data determined to be used to create the snapshot image as a result of the profiling described above, a process of determining the number of pieces of data to be used to create the snapshot image is executed. For example, for five pieces of data in total, which are included in the image lists shown in FIGS. 7 and 8, the process of determining how many pieces of data out of the five are included in the snapshot image is executed.

Typically, on the basis of a speed of reading the data and the information of the image lists from the storage device 4 to the main memory 2 and an average process time spent on reading the data from the swap device 5 to the main memory 2 when the page fault occurs, the control unit 1 determines the number of pieces of data to be used to create the snapshot image. The process is performed after the image list is created in the profiling mode.

Here, the size of the minimization image, the speed of reading the data (page) from the storage device 4 to the main memory 2, and the number of pieces of data to be included in the snapshot image are represented by M (MB), x (MB/sec), E (unknown), respectively. Further, the size of one page is represented by PAGE SIZE (typically, 4 KB), and a total entry count included in the image list is represented by Emax (five in the example shown in FIGS. 7 and 8). Further, an average process time spent on reading the data (page) from the swap device 5 (storage device 4 in the case where the storage device 4 has the function of the swap device 5) to the main memory 2 when the page fault occurs is represented by Tf (sec). In addition, a device access time after returning with the use of the snapshot image is represented by Td (sec). In this case, the control unit 1 determines the number of pieces of data to be used to create the snapshot image by using the following expression.

M+E*PAGESIZE/x+(Emax-E)*Tf<M+Emax*PAGESIZE/x+Td

FIG. 13 is a diagram for explaining meanings of the left-hand side and the right-hand side of the expression. With reference to the upper side in FIG. 13, M/x on the left-hand side of the expression indicates time spent on reading the minimization image from the storage device 4 to the main memory 2. Further, E*PAGESIZE/x represents time spent on reading the pieces of data from the storage device 4 to the main memory 2, when the number of pieces of data included in the snapshot image is assumed to be E (unknown).

Further, (Emax-E) represents the number of pieces of data that are included in the image list but is not included in the snapshot image. That is, (Emax-E) represents the number of pieces of data read from the swap device 5. Then, (Emax-E)*Tf represents time spent on reading (Emax-E) pieces of data from the swap device 5.

That is, the left-hand side of the expression indicates time spent on the activation in the case where the number of pieces of data included in the snapshot image is assumed to be E (unknown).

With reference to the lower side in FIG. 13, in the right-hand side of the expression, M/x represents time spent on reading the minimization image from the storage device 4 to the main memory 2. Further, Emax*PAGESIZE/x represents time spent on reading the data from the storage device 4 to the main memory 2 in the case where the entire data included in the image list is included in the snapshot image. Further, Td represents a device access time after returning with the use of the snapshot image

That is, the right-hand side of the expression indicates time spent on the activation in the case where the entire data included in the image list is included in the snapshot image.

It should be noted that, in the left-hand side of the expression, the device access time Td after the returning with the use of the snapshot image is not indicated. This is because Td is spent in parallel with the reading of the (Emax-E) pieces of data from the swap device 5.

When the activation time period in the case where the number of pieces of data included in the snapshot image is represented by E (left-hand side) becomes smaller than the activation time period in the case where the entire data in the image list is included in the snapshot image (right-hand side), the activation time is shortened.

For example, the control unit 1 determines E on the basis of the expression after the image list is created. Then, when creating the snapshot image, the control unit 1 reads E pieces of data of the entire data in the image list to the main memory 2 to create the snapshot image. As a result, the snapshot image capable of further shortening the activation time is created. It should be noted that typically, E pieces of data are used to create the snapshot image in chronological order of being profiled.

### Third Embodiment

Next, a third embodiment of the present technology will be described.

In the third embodiment, from the data (data in the image lists) determined to be used to create the snapshot image as a result of the profiling described above, data to be used to create the snapshot image is further determined. This point is different from the above embodiments.

In the third embodiment, the case where the control unit 1 has two CPUs is assumed. One of the two CPUs executes a process of starting up the system (OS) by using the snapshot image. The other CPU executes a process of starting up another system when the one CPU is starting up the system by using the snapshot image.

In such a case, the case where the size of the snapshot image is large is considered. In this case, when the one CPU starts a process of reading the data in the snapshot image to the main memory 2, a band of the bus 6 is compressed, and therefore it may be impossible for the other CPU to quickly start up another system. In this case, an overall activation start time of the system is delayed.

In view of this, in the third embodiment, from the data in the image lists, the data to be used to create the snapshot image is determined, thereby performing a process of reducing the size of the snapshot image. In this way, by reducing the size of the snapshot image, the load on the bus 6 due to the reading of the snapshot image to the main memory 2 is reduced.

With reference to FIG. 14, a specific process of the third embodiment will be described. FIG. 14 is a diagram for explaining the process of the electronic apparatus 10 according to the third embodiment.

After the image lists (see, FIGS. 7 and 8) are created by the profiling, on the basis of the time information of the image lists, the control unit 1 obtains time information Tmax of data which is profiled last.

Then, the control unit 1 divides Tmax into time zones T1 to Tn with a section time T. The section time T can be arbitrarily set. On the basis of the time information of the image lists, the control unit 1 creates a frequency distribution of data included in the time zones T1 to Tn.

Then, the control unit 1 determines whether the number of pieces (frequency) of data in the time zones T1 to Tn exceeds a predetermined threshold value Th or not. The predetermined threshold value Th may be an average value of the number of pieces of data in the time zones T1 to Tn. Alternatively, the predetermined threshold value Th may be preset from the viewpoint of reducing the load on the bus 6.

Then, for each of the time zones in which the number of pieces of data exceeds the predetermined threshold value Th, it is determined that data corresponding to the part (shaded part of FIG. 14) that exceeds the predetermined threshold value is data to be used to create the snapshot image. Then, when creating the snapshot image, the control unit 1 reads the data corresponding to the part that exceeds the predetermined threshold value to the main memory 2, from the entire data in the image list, thereby creating the snapshot image.

That is, on the basis of the time information of the image lists, the control unit 1 determines the time zones T1 to Tn in which the data is highly frequently read, and uses a part of the data read in the main memory 2 in the time zones in which the data is highly frequently read, thereby creating the snapshot image.

In the case where the activation is performed by using the snapshot image created through the above process, after the data in the snapshot image is read to the main memory 2, the page fault occurs. However, the data at the time when the page fault highly frequently occurs is included in the snapshot image, so the frequency of the occurrence of the page fault does not exceed a certain value.

That is, in the third embodiment, during a time period when the one CPU that starts up the system (OS) does not access the bus 6, the other CPU can access the bus 6. As a result, a high-speed startup of the entire system is achieved.

It should be noted that the technology according to the second embodiment and the technology according to the third embodiment can be combined with each other.

### Various Modified Examples

The present disclosure can take the following configurations.

(1) An electronic apparatus, including:

a volatile memory;

a swap device; and

a control unit configured to divide data loaded in the volatile memory between an activation start and a specific time point after the activation start into data used to create a snapshot image and data stored in the swap device.

(2) The electronic apparatus according to Item (1), in which

the control unit performs a profiling mode in which, from data loaded in the volatile memory between the activation start and the specific time point after the activation start, data to be used to create the snapshot image is determined by profiling.

(3) The electronic apparatus according to Item (2), in which

the control unit determines data to be used to create the snapshot image by profiling relating to reading data to the volatile memory in the profiling mode.

(4) The electronic apparatus according to Item (3), in which

the control unit stops a read-ahead function of an OS (operating system) in the profiling mode.

(5) The electronic apparatus according to Item (3) or (4), in which

the control unit creates a list relating to which data is used to create the snapshot image by the profiling.

(6) The electronic apparatus according to any one of Items (2) to (5), in which

after the profiling mode is performed, the control unit reads the data determined to be used to create the snapshot image by the profiling to the volatile memory and performs a snapshot image creation mode in which the snapshot image is created based on the data read to the volatile memory.

(7) The electronic apparatus according to Item (6), in which

the control unit stops a read-ahead function of an OS (operating system) in the snapshot image creation mode.

(8) The electronic apparatus according to any one of Items (2) to (7), in which

the control unit performs, prior to the profiling mode, a preparation mode in which the data is loaded into the volatile memory by normal activation from the activation start until the specific time point after the activation start.

(9) The electronic apparatus according to Item (8), in which

the control unit performs swap-out of data used in an application program, of the data loaded into the volatile memory between the activation start and the specific time point after the activation start, to the swap device in the preparation mode.

(10) The electronic apparatus according to Item (9), in which

after the swap-out of the data is performed, the swap device is brought into a read-only state.

(11) The electronic apparatus according to Item (9) or (10), in which

the control unit deletes the application program and a page cache, from the data loaded into the volatile memory between the activation start and the specific time point after the activation start, in the preparation mode.

(12) The electronic apparatus according to Item (11), in which

the control unit creates, in the preparation mode, snapshot image at a stage prior to creation of a last snapshot image based on data in the volatile memory, which is obtained after the swap-out of the data used in the application program and the deletion of the application program and the page cache.

(13) The electronic apparatus according to any one of Items (2) to (12), in which

the control unit determines the number of pieces of data to be used to create the snapshot image for the data determined to be used to create the snapshot image by the profiling.

(14) The electronic apparatus according to Item (13), in which

the control unit determines the number of pieces of data to be used to create the snapshot image based on a speed at a time when the data is read to the volatile memory and a process time spent on reading the data when a page fault occurs.

(15) The electronic apparatus according to any one of Items (2) to (14), in which

the control unit further determines data to be used to create the snapshot image, from the data determined to be used to create the snapshot image by the profiling.

(16) The electronic apparatus according to Item (15), in which

the control unit associates the data with time information that indicates time when the data is read to the volatile memory in the profiling mode, determines a time zone in which the data is highly frequently read based on the time information, and creates the snapshot image by using the data read to the volatile memory in the time zone in which the data is highly frequently read.

(17) A method of creating a snapshot image, including:

dividing data loaded in a volatile memory between an activation start and a specific time point after the activation start into data used to create a snapshot image and data stored in a swap device; and

creating the snapshot image based on the data used to create the snapshot image.

(18) A program causing an electronic apparatus to execute

dividing data loaded in a volatile memory between an activation start and a specific time point after the activation start into data used to create a snapshot image and data stored in a swap device, and

creating the snapshot image based on the data used to create the snapshot image.

It should be understood by those skilled in the art that various modifications, combinations, sub-combinations and alterations may occur depending on design requirements and other factors insofar as they are within the scope of the appended claims or the equivalents thereof.

What is claimed is:

1. An electronic apparatus, comprising:
a volatile memory;
a swap device; and
a control unit configured to divide data loaded in the volatile memory between an activation start and a specific time point after the activation start into data used to create a snapshot image and data stored in the swap device.

2. The electronic apparatus according to claim 1, wherein
the control unit performs a profiling mode in which, from data loaded in the volatile memory between the activation start and the specific time point after the activation start, data to be used to create the snapshot image is determined by profiling.

3. The electronic apparatus according to claim 2, wherein
the control unit determines data to be used to create the snapshot image by profiling relating to reading data to the volatile memory in the profiling mode.

4. The electronic apparatus according to claim 3, wherein
the control unit stops a read-ahead function of an OS (operating system) in the profiling mode.

5. The electronic apparatus according to claim 3, wherein
the control unit creates a list relating to which data is used to create the snapshot image by the profiling.

6. The electronic apparatus according to claim 2, wherein
after the profiling mode is performed, the control unit reads the data determined to be used to create the snapshot image by the profiling to the volatile memory and performs a snapshot image creation mode in which the snapshot image is created based on the data read to the volatile memory.

7. The electronic apparatus according to claim 6, wherein
the control unit stops a read-ahead function of an OS (operating system) in the snapshot image creation mode.

8. The electronic apparatus according to claim 2, wherein
the control unit performs, prior to the profiling mode, a preparation mode in which the data is loaded into the volatile memory by normal activation from the activation start until the specific time point after the activation start.

9. The electronic apparatus according to claim 8, wherein
the control unit performs swap-out of data used in an application program, of the data loaded into the volatile memory between the activation start and the specific time point after the activation start, to the swap device in the preparation mode.

10. The electronic apparatus according to claim 9, wherein
after the swap-out of the data is performed, the swap device is brought into a read-only state.

11. The electronic apparatus according to claim 9, wherein
the control unit deletes the application program and a page cache, from the data loaded into the volatile memory between the activation start and the specific time point after the activation start, in the preparation mode.

12. The electronic apparatus according to claim 11, wherein
the control unit creates, in the preparation mode, a snapshot image at a stage prior to creation of a last snapshot image based on data in the volatile memory, which is obtained after the swap-out of the data used in the application program and the deletion of the application program and the page cache.

13. The electronic apparatus according to claim 2, wherein
the control unit determines the number of pieces of data to be used to create the snapshot image for the data determined to be used to create the snapshot image by the profiling.

14. The electronic apparatus according to claim 13, wherein
the control unit determines the number of pieces of data to be used to create the snapshot image based on a speed at a time when the data is read to the volatile memory and a process time spent on reading the data when a page fault occurs.

15. The electronic apparatus according to claim 2, wherein
the control unit further determines data to be used to create the snapshot image, from the data determined to be used to create the snapshot image by the profiling.

16. The electronic apparatus according to claim 15, wherein
the control unit associates the data with time information that indicates time when the data is read to the volatile memory in the profiling mode, determines a time zone in which the data is highly frequently read based on the time information, and creates the snapshot image by using the data read to the volatile memory in the time zone in which the data is highly frequently read.

17. A method of creating a snapshot image, comprising:
dividing data loaded in a volatile memory between an activation start and a specific time point after the activation start into data used to create a snapshot image and data stored in a swap device; and
creating the snapshot image based on the data used to create the snapshot image.

18. A program causing an electronic apparatus to execute
dividing data loaded in a volatile memory between an activation start and a specific time point after the activation start into data used to create a snapshot image and data stored in a swap device, and
creating the snapshot image based on the data used to create the snapshot image.
